(19) United States
(12) Patent Application Publication
(10) Pub. No.: US 2016/0128233 A1
(43) Pub. Date: May 5, 2016

(54) HEAT SINK MODULE FOR MOBILE ELECTRONIC APPARATUS

(71) Applicant: TAI-SOL ELECTRONICS CO., LTD., TAIPEI CITY (TW)

(72) Inventor: Yaw-Huey LAI, TAIPEI CITY (TW)

(21) Appl. No.: 14/582,695

(22) Filed: Dec. 24, 2014

(30) Foreign Application Priority Data
Oct. 29, 2014 (TW) 103137379

(51) Int. Cl. H05K 7/20; F28D 15/04

(52) U.S. Cl. CPC H05K 7/20336; F28D 15/04

(57) ABSTRACT

A heat sink module used in a mobile electronic apparatus having a front face panel and a back cover is disclosed to include a frame set between the front face panel and the back cover and defining therein an accommodation portion, a first panel member mounted in the frame within the accommodation portion, a second panel member bonded to the first panel member and defining with the first panel member an enclosed chamber, a first wick layer located at one surface of the first panel member in the enclosed chamber, a second wick layer located at one surface of the second panel member in the enclosed chamber and defining with the first wick layer a gas flow path therebetween, and a working fluid contained in the enclosed chamber.

### BACKGROUND OF THE INVENTION

1. Field of the Invention

The present invention relates to heat dissipation technology and more particularly, to a heat sink module for mobile electronic apparatus.

2. Description of the Related Art

With advances in technology, mobile electronic apparatus (such as mobile phone, tablet computer, PDA, etc.) has become an essential tool for modern people for dialing a telephone number, linking to the Internet, browsing a website, receiving and transmitting an e-mail, running an APP software, and performing other functions.

Therefore, the function and operating speed of mobile electronic apparatus have been greatly improved. Further, the use of high speed CPUs and IC chips will encounter a heating problem. If the temperature of the mobile electronic apparatus is too high, it will cause the user to feel uncomfortable. Therefore, the problem of heat dissipation of mobile electronic apparatus has gotten people's attention.

Taiwan Patent M460507 discloses a shell structure for mobile phone, which provides a vapor chamber heat spreader made in the shape of a back shell for mobile phone, or the inform of a part of back shell for mobile phone for quick dissipation of heat by means of its rapid heat transfer characteristic. However, making a vapor chamber heat spreader for use as a part or the whole of a back shell for mobile phone can simply dissipate heat from the internal heat elements that are disposed near the back side of the mobile phone. This problem limits the range of location selection for heat elements. Further, regular vapor chamber heat spreaders commonly have a flat design. For making a vapor chamber heat spreader in the shape of a back shell for mobile phone, or the inform of a part of back shell for mobile phone, the vapor chamber heat spreader must be configured to provide a curved part, or it cannot be formed in any curved area of the back shell. Further, making a vapor chamber heat spreader for use as a backs hell for mobile phone will encounter the problem of durability, and the vapor chamber heat spreader can be damaged easily to lose its cooling function when the mobile phone is hit by an external object or falls to the ground.

### SUMMARY OF THE INVENTION

The present invention has been accomplished under the circumstances in view. It is the main object of the present invention to provide a heat sink module for mobile electronic apparatus, which allows the vapor chamber heat spreader to be joined to the inside of a mobile electronic apparatus to provide a location for the positioning of the internal heating elements of the mobile electronic apparatus, facilitating component location design.

It is another object of the present invention to provide a heat sink module for mobile electronic apparatus, which allows the vapor chamber heat spreader to be joined to the inside of a mobile electronic apparatus so that is can be made without considering the configuration of the outer shell of the mobile electronic apparatus or how to get away from any curved surface.

It is still another object of the present invention to provide a heat sink module for mobile electronic apparatus, which allows the vapor chamber heat spreader to be joined to the inside of a mobile electronic apparatus, thus avoiding the problem of collision and breaking

To achieve these and other objects of the present invention, a heat sink module is disclosed for use in a mobile electronic apparatus having a front face panel and a back cover. The heat sink module comprises a frame set between the front face panel and the back cover and defining therein an accommodation portion, a first panel member mounted in the frame within the accommodation portion, a second panel member bonded to the first panel member and defining with the first panel member an enclosed chamber, a first wick layer located at one surface of the first panel member in the enclosed chamber, a second wick layer located at one surface of the second panel member in the enclosed chamber and defining with the first wick layer a gas flow path therebetween, and a working fluid contained in the enclosed chamber.

Thus, the first panel member and the second panel member are joined together to form a vapor chamber heat spreader, facilitating the installation of heating elements of the mobile electronic apparatus. In fabrication, the invention needs not to match with the configuration of the outer shell of the mobile electronic apparatus or to keep away from any curved outer surface in order to avoid the problem of collision or breaking.

Other and further benefits, advantages and features of the present invention will be understood by reference to the following specification in conjunction with the accompanying drawings, in which like reference characters denote like elements of structure.

### BRIEF DESCRIPTION OF THE DRAWINGS

FIG. 1 is an oblique top elevational view of a heat sink module in accordance with a first embodiment of the present invention.

FIG. 2 is an exploded view of the heat sink module in accordance with the first embodiment of the present invention.

FIG. 3 is a sectional view taken along line 3-3 of FIG. 1.

FIG. 4 is an enlarged view of a part of FIG. 3.

FIG. 5 is an oblique top elevational view illustrating the heat sink module installed in the mobile electronic apparatus.

FIG. 6 is an exploded view of the assembly shown in FIG. 5.

FIG. 7 is a sectional view, in an enlarged scale, of the assembly shown in FIG. 5.

FIG. 8 is an exploded view of a heat sink module in accordance with a second embodiment of the present invention.

FIG. 9 is a sectional view of the second embodiment of the present invention.

FIG. 10 is an exploded view of a heat sink module in accordance with a third embodiment of the present invention.

FIG. 11 is a sectional view of the third embodiment of the present invention.

### DETAILED DESCRIPTION OF THE INVENTION

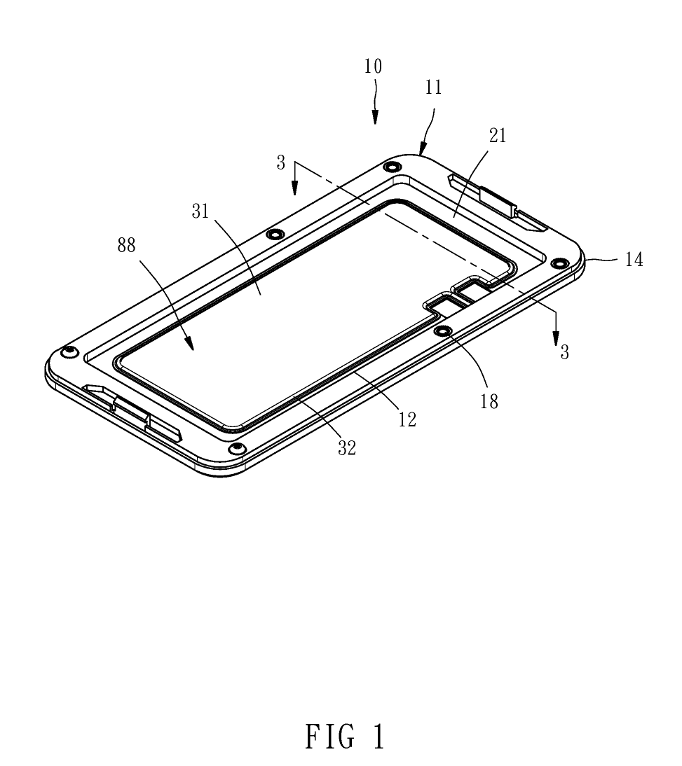

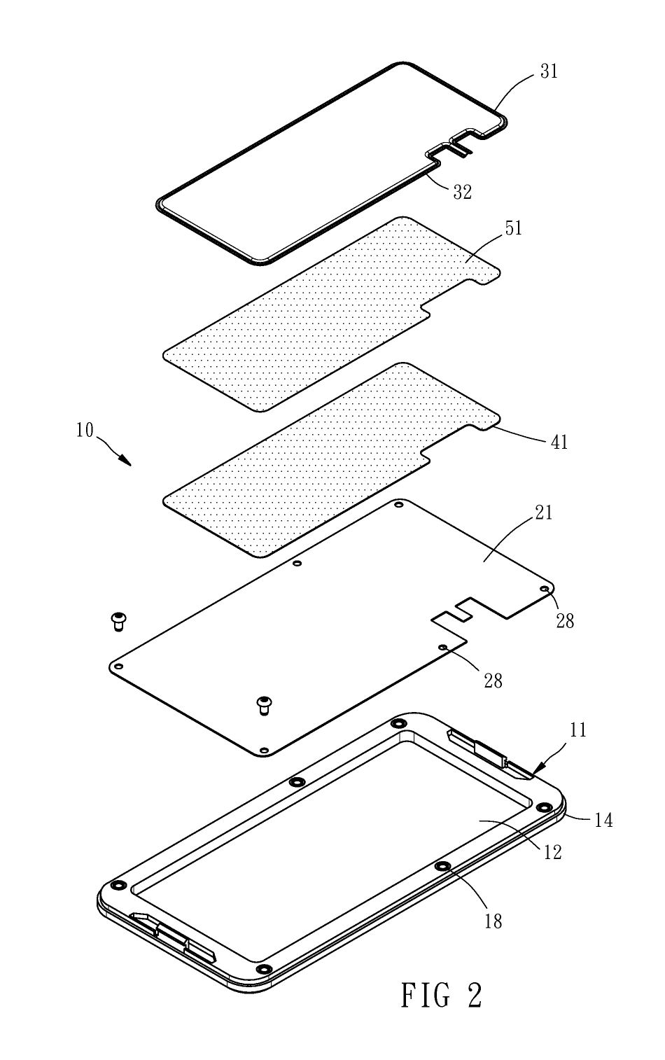

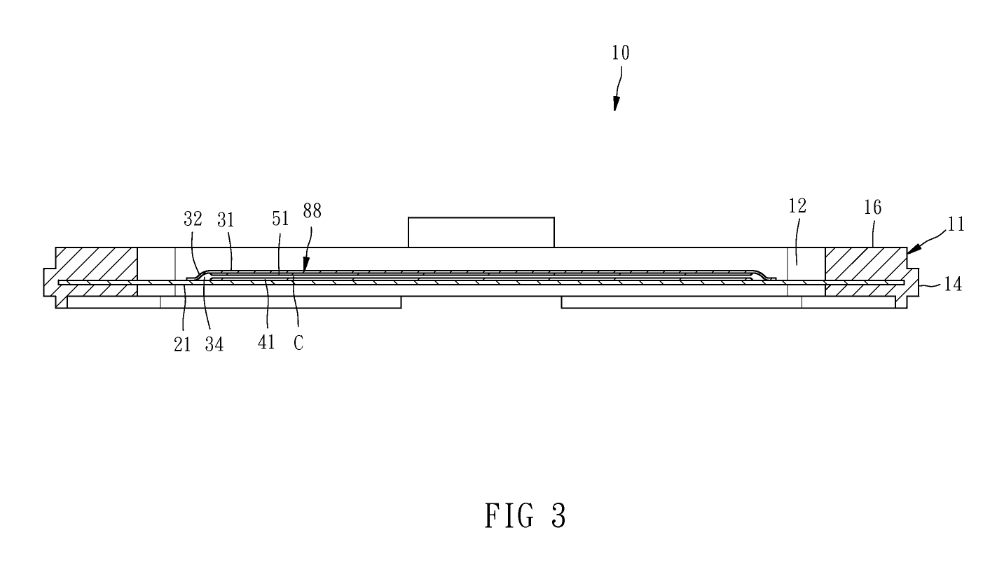

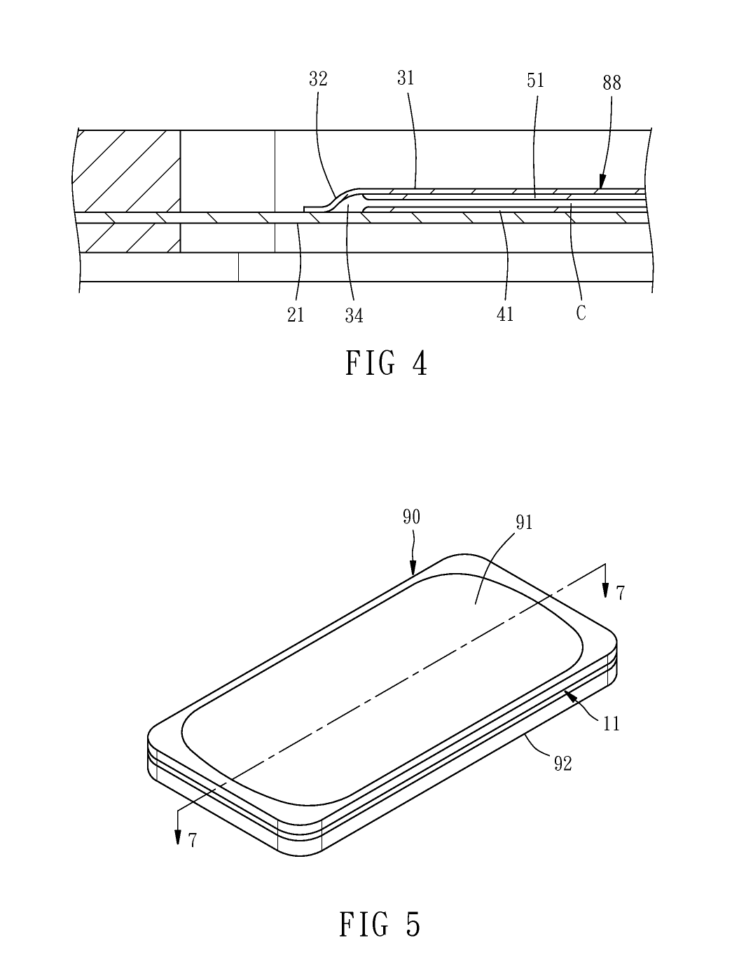

Referring to FIGS. 1-4, a heat sink module 10 for use in a mobile electronic apparatus 90 in accordance with a first embodiment of the present invention is shown. The mobile electronic apparatus 90 comprises a front face panel 91 and a back cover 92. The heat sink module 10 comprises a frame 11, a first panel member 21, a second panel member 31, a first wick layer 41, a second wick layer 51, and a working fluid (not shown).

The frame 11 is set between the front face panel 91 and the back cover 92, comprising an accommodation portion 12. In actual application, the frame 11 can be mounted within the front face panel 91 and the back cover 92, or with a part thereof exposed to the outside. In this first embodiment, the frame 11 has a part exposed to the outside of the front face panel 91 and back cover 92 of the mobile electronic apparatus 90, wherein the front face panel 91 and the back cover 92 define therebetween a gap around the periphery of the mobile electronic apparatus 90; the frame 11 comprises an endless rib 14 extending around the periphery thereof and fitted into the gap the front face panel 91 and the back cover 92, and thus, the outer surface of the endless rib 14 is exposed to the outside. In this first embodiment, the frame 11 is a plastic member made by insert molding.

The first panel member 21 is mounted in the frame 11 within the accommodation portion 12. In this first embodiment, the first panel member 21 is mounted in the frame 11 by insertion, and fills up the accommodation portion 12. This structural design facilitates fabrication. However, this structural design is not a limitation. In actual application, the first panel member 21 can be configured not to fill up the whole space of the accommodation portion 12.

The second panel member 31 is bonded to the first panel member 21, defining with the first panel member 21 an enclosed chamber 34. In this first embodiment, the second panel member 31 comprises a standing wall 32 extending around the border thereof and facing toward the first panel member 21. The standing wall 32 is bonded to the first panel member 21 by welding or thermal compression bonding. The enclosed chamber 34 is surrounded by the standing wall 32. The second panel member 31 is located in the accommodation portion 12 without contacting the frame 11. Further, the outer surface of the second panel member 31 is a planar surface.

The first wick layer 41 is located at one surface of the first panel member 21 in the enclosed chamber 34.

The second wick layer 51 is located at one surface of the second panel member 31 in the enclosed chamber 34, defining with the first wick layer 41 a gas flow path C therebetween.

The first wick layer 41 and the second wick layer 51 are sintered from copper powder or netting.

The working fluid (not shown) is filled in the enclosed chamber 34. Because the working fluid is absorbed in the first wick layer 41 or second wick layer 51, it is difficult to indicate the working fluid in the drawings. Further, the working fluid is an ordinary component known to any person skilled in the art, it is not specified in the drawings.

Thus, the first panel member 21, the second panel member 31, the first wick layer 41, the second wick layer 51 and the working fluid are joined together to form a vapor chamber vapor chamber heat spreader 88.

In this first embodiment, the frame 11 further comprises a plurality of through holes 18 cut through opposing front and back sides thereof; the first panel member 21 comprises a plurality of through holes 28 respectively aimed at the through holes 18 of the frame 11. Screws (not shown) are respectively fastened to the through holes 18,28 to affix the frame 11 and the first panel member 21 to the mobile electronic apparatus 90.

As stated above, the invention provides a heat sink module 10 comprised of a vapor chamber heat spreader 88 and a frame 11 for mounting in a mobile electronic apparatus 90.

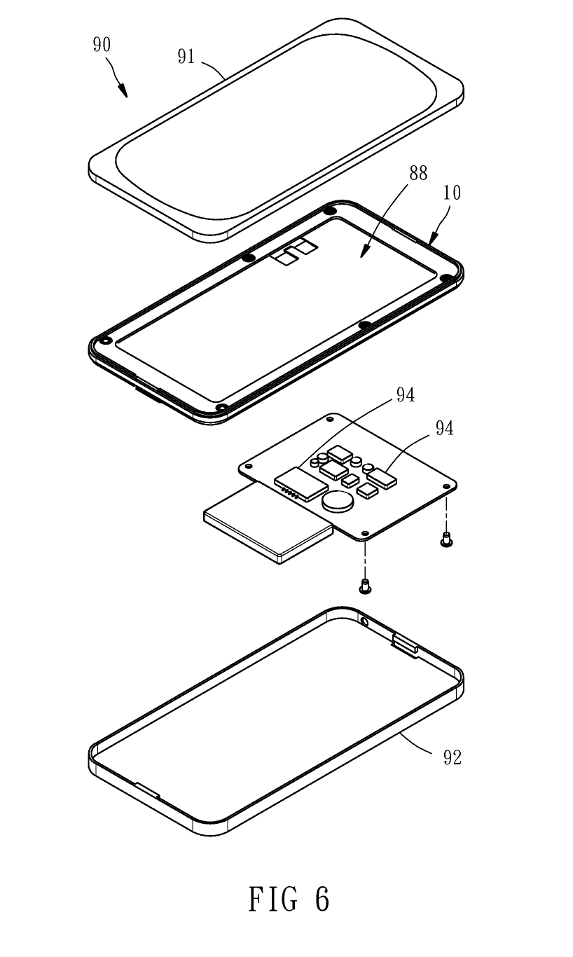

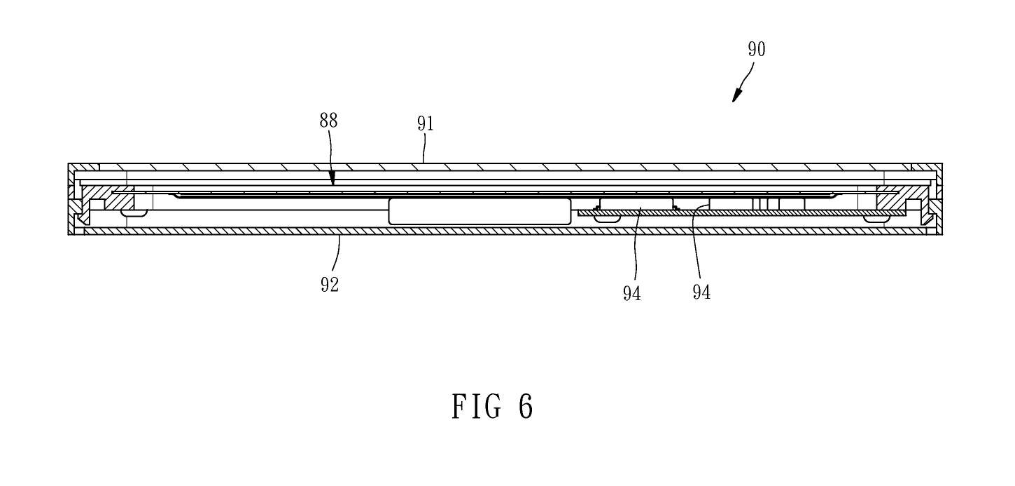

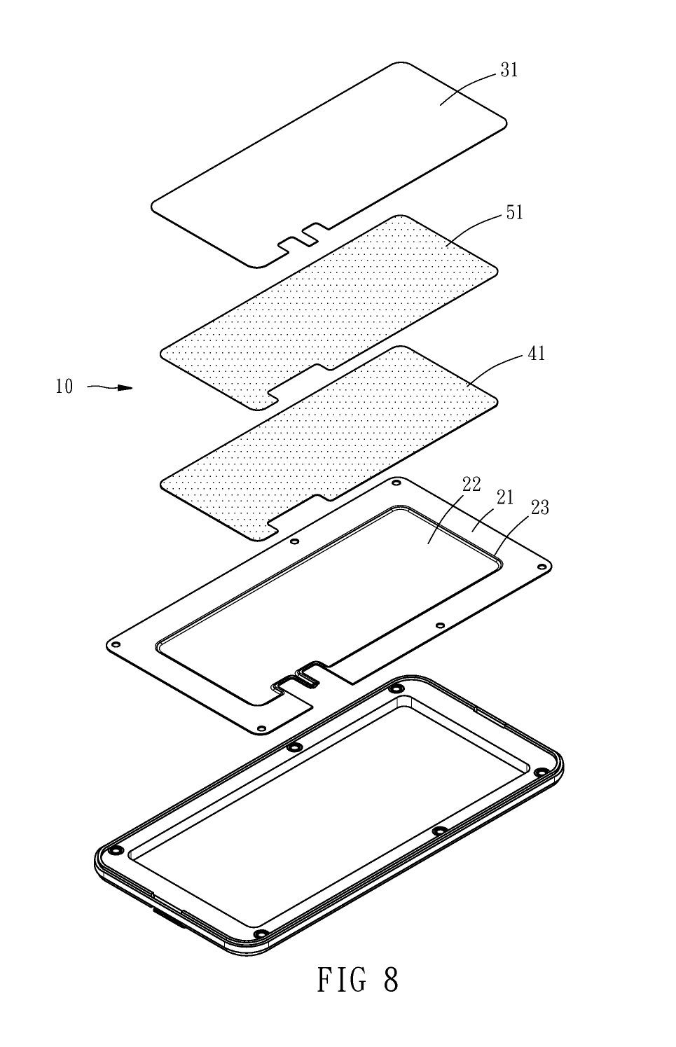

Referring to FIGS. 5-7, the assembly of the heat sink module 10 in accordance with the first embodiment is shown in the reversed direction relative to FIG. 1. After installation of the heat sink module 10 in the mobile electronic apparatus 90, the vapor chamber heat spreader 88 is positioned inside the mobile electronic apparatus 90, enabling a plurality of electronic components 94 to be kept in contact with the vapor chamber heat spreader 88 to achieve good heat transfer performance. When designing the allocation of related circuit boards and electronic components 94, the invention provides high flexibility and convenience. Further, by means of joining the vapor chamber heat spreader 88 to the inside of the mobile electronic apparatus 90, the vapor chamber heat spreader 88 does not need to match with the configuration of the outer shell of the mobile electronic apparatus 90, avoiding the vapor chamber heat spreader 88 from being crashed and broken accidentally.

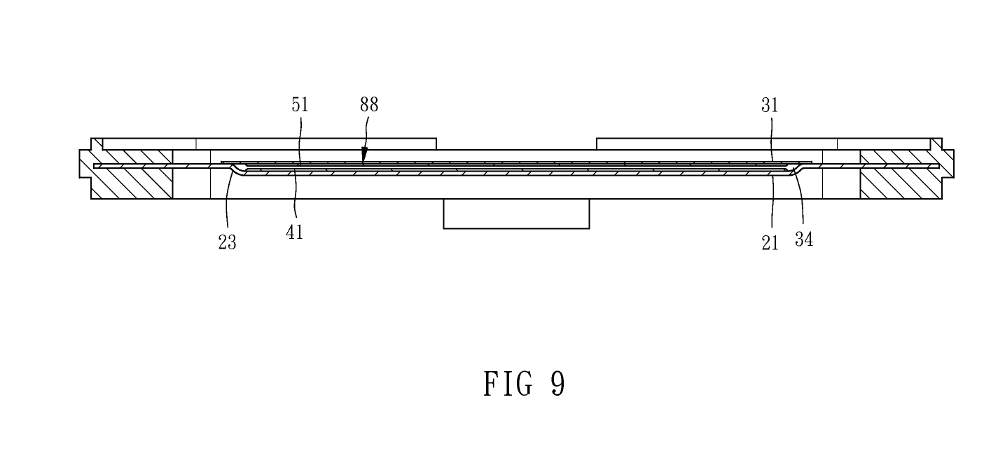

Referring to FIGS. 8 and 9, a heat sink module 10′ for mobile electronic apparatus in accordance with a second embodiment of the present invention is shown. This second embodiment is substantially similar to the aforesaid first embodiment with the exceptions as follows:

The second panel member 31′ eliminates the aforesaid standing wall; the first panel member 21′ comprises a recessed portion 22′extending in direction reversed to the location of the second panel member 31′, and a standing wall 23′ extending around the recessed portion 22′. The second panel member 31′ is affixed to the first panel member 21′ by welding. The enclosed chamber 34′ is formed in the recessed portion 22′.

Thus, the first panel member 21′, the second panel member 31′, the first wick layer 41′, the second wick layer 51′ and the working fluid are joined together to form a vapor chamber heat spreader 88′.

The other structural features and the effects of this second embodiment are same as the aforesaid first embodiment.

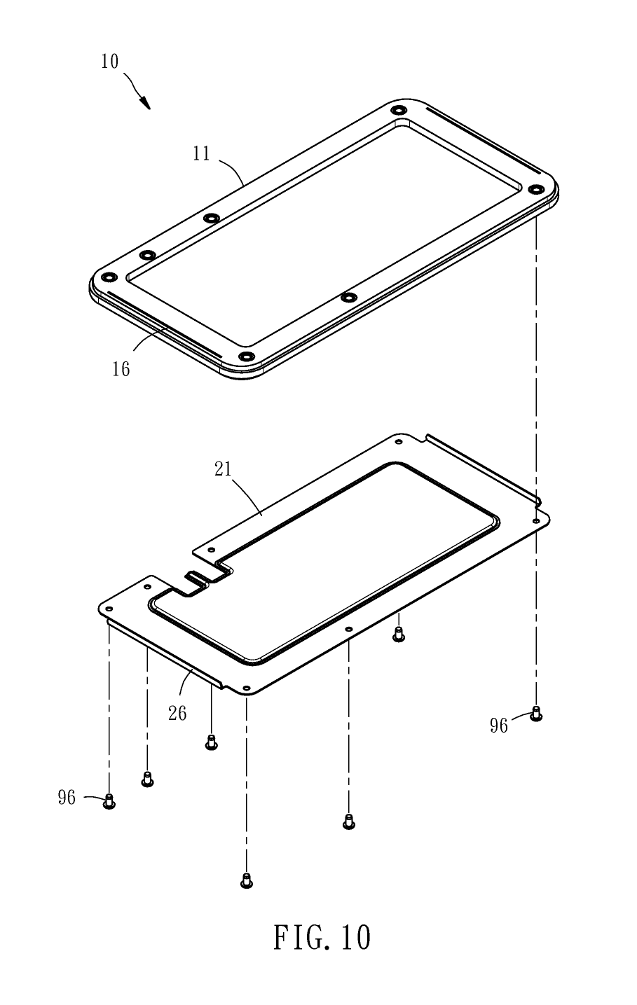

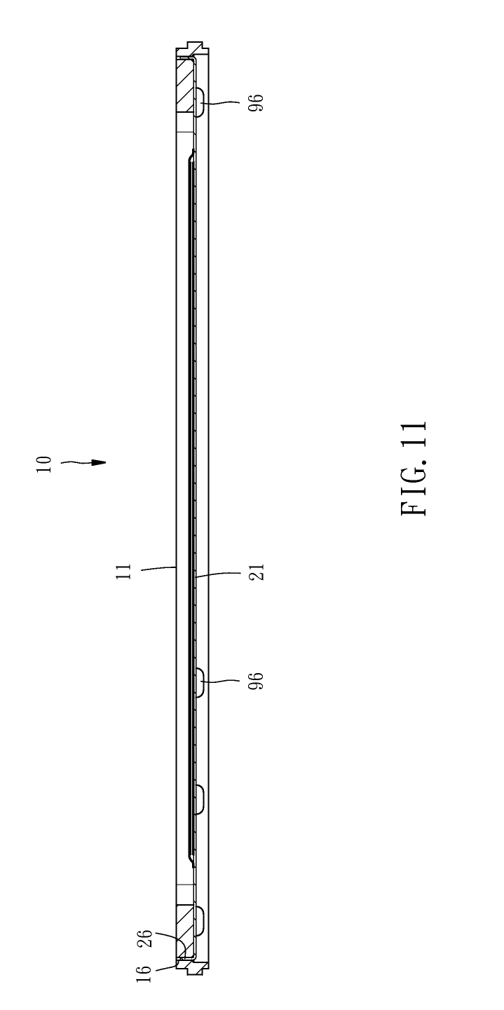

Referring to FIGS. 10 and 11, a heat sink module 10″ for mobile electronic apparatus in accordance with a third embodiment of the present invention is shown. This third embodiment is substantially similar to the aforesaid first embodiment with the exceptions as follows:

The first panel member 21″ is joined to the frame 11″ by an assembly process instead of insert molding. In this third embodiment, the first panel member 21″ comprises two plug portions 26″ respectively located at two opposite ends thereof; the frame 11″ comprises two plug holes 16″ for receiving the plug portions 26″ of the first panel member 21″ respectively. By means of plugging the plug portions 26″ of the first panel member 21″ into the respective plug holes 16″ of the frame 11″, the first panel member 21″ is joined to the frame 11″. Further, screws 96 can be installed to affix the first panel member 21″ to the frame 11″, enhancing connection stability. Further, it will be appreciated that the first panel member 21″ and the frame 11″ can be joined together by tight fit instead of the aforesaid plug joint or the use of screws. This tight fit method is a known technique, and therefore it is not explained by illustration. Therefore, the aforesaid assembly process or insert molding is not a limitation.

Thus, the component parts of the present invention can be joined together in a convenient and cost-effective manner.

The other structural features and the effects of this third embodiment are same as the aforesaid first embodiment.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A heat sink module used in a mobile electronic apparatus comprising a front face panel and a back cover, said heat sink module comprising:
a frame set between said front face panel and said back cover, said frame comprising an accommodation portion;
a first panel member mounted in said frame within said accommodation portion;
a second panel member bonded to said first panel member and defining with said first panel member an enclosed chamber;
a first wick layer located at one surface of said first panel member in said enclosed chamber;
a second wick layer located at one surface of said second panel member in said enclosed chamber and defining with said first wick layer a gas flow path therebetween; and
a working fluid contained in said enclosed chamber.

2. The heat sink module as claimed in claim 1, wherein said frame has the periphery thereof exposed to the outside of said front face panel and said back cover of said mobile electronic apparatus.

3. The heat sink module as claimed in claim 2, wherein said front face panel and said back cover define therebetween a gap extending around the periphery of said mobile electronic apparatus; said frame comprises an endless rib extending around the periphery thereof and fitted into said gap between said front face panel and said back cover and exposed to the outside of said mobile electronic apparatus.

4. The heat sink module as claimed in claim 1, wherein said first panel member fills up said accommodation portion.

5. The heat sink module as claimed in claim 1, wherein said second panel member comprises a standing wall extending around the border thereof and facing toward said first panel member, said standing wall being bonded to said first panel member; said enclosed chamber is surrounded by said standing wall.

6. The heat sink module as claimed in claim 1, wherein said first panel member comprises a recessed portion extending in direction reversed to the location of the second panel member, and a standing wall extending around said recessed portion.

7. The heat sink module as claimed in claim 1, wherein said second panel member is located in said accommodation portion and kept apart from said frame.

8. The heat sink module as claimed in claim 1, wherein said second panel member comprises an outer planar surface opposite to said first panel member.

9. The heat sink module as claimed in claim 1, wherein said frame comprises plurality of through holes cut through opposing front and back sides thereof; said first panel member comprises a plurality of through holes respectively aimed at the through holes of said frame.

10. The heat sink module as claimed in claim 1, wherein said first panel member and said second panel member are fixedly connected together by welding or thermal compression bonding.

11. The heat sink module as claimed in claim 1, wherein said first panel member is mounted in said frame by insert molding.

12. The heat sink module as claimed in claim 1, wherein said first panel member is connected to said frame by an assembly process.
